(19) United States
(12) Patent Application Publication
(10) Pub. No.: US 2026/0157240 A1
(43) Pub. Date: Jun. 4, 2026

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Gi Tae LIM, Seoul (KR); Min Hwa CHANG, Incheon (KR)

(73) Assignee: Amkor Technology Singapore Holding Pte. Ltd., Valley Point #12-03 (SG)

(21) Appl. No.: 18/967,838

(22) Filed: Dec. 4, 2024

(51) Int. Cl. H01L 23/498; H01L 21/48; H01L 21/56; H01L 23/00; H01L 23/31; H01L 23/538; H01L 25/16

(52) U.S. Cl. CPC H10W 90/401; H10W 70/093; H10W 70/611; H10W 70/65; H10W 74/016; H10W 74/117; H10W 90/00; H10W 90/701; H10W 72/884; H10W 74/15; H10W 90/724; H10W 90/732; H10W 90/734; H10W 90/754

(57) ABSTRACT

A packaged electronic device structure includes a first electronic device with a first substrate, a first electronic component coupled to the first substrate, a first encapsulant covering the first electronic component, and first external interconnects coupled to the first substrate. The first external interconnects are coupled to a second substrate, a second electronic component is coupled to the second substrate, and a second encapsulant is interposed between the first substrate and the second substrate and covers the first external interconnects and the second electronic component. A second electronic device includes a third substrate. A third electronic component is coupled to the third substrate. Vertical interconnects couple the second substrate to the third substrate and a third encapsulant is interposed between the second substrate and the third substrate and covers the vertical interconnects and the third electronic component. Second external interconnects are coupled to the third substrate.

### CROSS-REFERENCE TO RELATED APPLICATIONS

Not applicable.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, and 2G show cross-sectional views of an example method for manufacturing an example electronic device; FIG. 2BA shows a plan view of the example electronic device of FIG. 2B; and FIG. 2EA shows a plan view of the example electronic device of FIG. 2E.

FIG. 3 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical or electrical coupling.

### DESCRIPTION

The present description includes, among other features, structures and associated methods that relate to electronic devices that are more resilient to stresses encountered during manufacturing or during the usage of the electronic devices. More particularly, structures and methods are described that improve the reliability of electronic devices that reduce defects associated with stress, such as solder ball cracking. In some examples, the structures and methods are useful for Package on Package (PoP) package structures where multiple structures are stacked and bonded to each other. One type of PoP technology is referred to as an Interposer PoP (IPPoP) technology where in some examples, a top interposer is attached to a bottom substrate using thermocompression bonding with metal core balls, such as copper core balls (CCB). The CCB connection between the bottom substrate and the interposer allows for high speed and high-density interconnect access to an electronic device mounted to the top side of the interposer.

In previous IPPoP technology, a gap or open space existed between the electronic device and the top side of the interposer and between the interconnects connecting the electronic device to the top side of the interposer. It was found in some applications that the interconnects were susceptible to stress cracking particularly with higher densities of interconnects. Accordingly, structures and methods are described that provide a molded encapsulant within the gap to protect the interconnects. In some examples, a transfer molding process is used to provide the molded encapsulant between the electronic device and the top side of the interposer prior to attaching the interposer substrate to the bottom substrate. The molded encapsulant has advantages over other materials, such as capillary underfill materials, including no need for keep out zone (KOZ) considerations, which unfavorably increase package size. Also, the approach avoids using tape assisted processing or other expensive molding techniques, which reduces process complexities and costs.

In an example, a packaged electronic device structure includes a first electronic device. The first electronic device includes a first substrate including a first substrate first side and a first substrate second side opposite the first substrate first side, and a first substrate conductive structure. The first electronic device includes a first electronic component coupled to the first substrate conductive structure at the first substrate first side, a first encapsulant covering the first electronic component, and first external interconnects coupled to the first substrate conductive structure at the first substrate second side. The packaged electronic device structure includes a second substrate including a second substrate first side and a second substrate second side opposite the second substrate first side, a second substrate conductive structure, and a second substrate dielectric structure. The first external interconnects are coupled to the second substrate conductive structure at the second substrate first side. The packaged electronic device structure includes a second electronic component coupled to the second substrate first side and a second encapsulant interposed between the first substrate and the second substrate and covering the first external interconnects, the second substrate first side, the first substrate second side, and the second electronic component. The packaged electronic device structure includes a second electronic device including a third substrate. The third substrate includes a third substrate first side and a third substrate second side opposite to the third substrate first side, and a third substrate conductive structure. The second electronic device includes a third electronic component coupled to the third substrate conductive structure at the third substrate first side. The packaged electronic device structure includes vertical interconnects coupled to the second substrate conductive structure at the second substrate second side and coupled to the third substrate conductive structure at the third substrate first side, a third encapsulant interposed between the second substrate and the third substrate and covering the vertical interconnects and the third electronic component, and second external interconnects coupled the third substrate conductive structure at the third substrate second side.

In an example, a method of manufacturing a packaged electronic device structure includes providing a first electronic device including a first substrate including a first substrate first side and a first substrate second side opposite the first substrate first side, and a first substrate conductive structure; a first electronic component coupled to the first substrate conductive structure at the first substrate first side; a first encapsulant covering the first electronic component; and first external interconnects coupled to the first substrate conductive structure at the first substrate second side. The method includes providing a second substrate includes a second substrate first side and a second substrate second side opposite the second substrate first side, a second substrate conductive structure, and a second substrate dielectric structure. The method includes coupling the first external interconnects to the second substrate conductive structure at the second substrate first side. The method includes providing a second encapsulant interposed between the first substrate and the second substrate and covering the first external interconnects, the second substrate first side, and the first substrate second side. The method includes providing first vertical interconnects coupled to the second substrate conductive structure at the second substrate second side. The method includes providing a second electronic device including a third substrate including a third substrate first side and a third substrate second side opposite to the third substrate first side, and a third substrate conductive structure; and a second electronic component coupled to the third substrate conductive structure at the third substrate first side. The method includes after providing the second encapsulant, (a) coupling the first vertical interconnects to the third substrate conductive structure at the third substrate first side, and (b) providing a third encapsulant interposed between the second substrate and the third substrate and covering the first vertical interconnects and the second electronic component.

In an example, a method of manufacturing a packaged electronic device structure includes providing a first electronic device including a first substrate including a first substrate first side and a first substrate second side opposite the first substrate first side, and a first substrate conductive structure; a first electronic component coupled to the first substrate conductive structure at the first substrate first side; a first encapsulant covering the first electronic component; and first external interconnects coupled to the first substrate conductive structure at the first substrate second side. The method includes providing a second substrate including a second substrate first side and a second substrate second side opposite the second substrate first side, a second substrate conductive structure, and a second substrate dielectric structure. The method includes coupling the first external interconnects to the second substrate conductive structure at the second substrate first side. The method includes providing a second encapsulant interposed between the first substrate and the second substrate and covering the first external interconnects, the second substrate first side, and the first substrate second side. The method includes coupling first vertical interconnects to the second substrate conductive structure at the second substrate second side. The method includes after providing the second encapsulant, (a) providing a second electronic device including a third substrate including a third substrate first side and a third substrate second side opposite to the third substrate first side, and a third substrate conductive structure; and a second electronic component coupled to the third substrate conductive structure at the third substrate first side; (b) coupling the first vertical interconnects to the third substrate conductive structure at the third substrate first side; and (c) providing a third encapsulant interposed between the second substrate and the third substrate and covering the first vertical interconnects and the second electronic component.

Other examples are included in the present disclosure. Such examples may be found in the figures, in the claims, or in the description of the present disclosure.

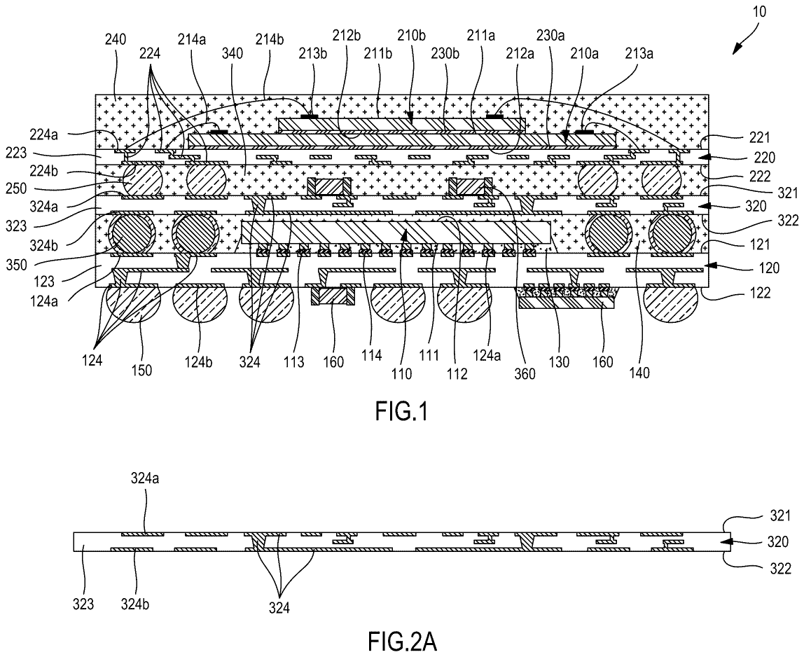

FIG. 1 shows a cross-sectional view of an example packaged electronic device structure 10. In the example shown in FIG. 1, packaged electronic device structure 10 can comprise electronic component 110, electronic component 210a, electronic component 210b, primary substrate 120, underfill material 130, encapsulant 140, encapsulant 240, encapsulant 340, primary external interconnects 150, substrate 220, die attach material 230a, die attach material 230b, external interconnects 250, interposer substrate 320, and vertical interconnects 350. In some examples, packaged electronic device structure 10 can comprise electronic component 160 and electronic component 360.

In some examples, electronic component 110 comprises first side 111 and second side 112 opposite to first side 111; electronic component 210a comprises first side 211a and second side 212a opposite to first side 211a; and electronic component 210b comprises first side 211b and second side 212b opposite to first side 211b. Electronic component 110, electronic component 210a, and electronic component 210b can each comprise contact pads 113, 213a, 213b and interconnects 114, 214a, and 214b on first sides 111, 211a, and 211b respectively.

Primary substrate 120 can comprise first side 121 and second side 122 opposite to first side 121. In some examples, primary substrate 120 can comprise dielectric structure 123 and conductive structure 124. Conductive structure 124 can comprise primary substrate inward terminals 124a located on first side 121 of primary substrate 120 and primary substrate outward terminals 124b located on second side 122 of primary substrate 120. Primary substrate 120 can comprise or also be referred to as a first substrate.

Substrate 220 can comprise first side 221 and second side 222 opposite to first side 221. In some examples, substrate 220 can comprise dielectric structure 223 and conductive structure 224. Conductive structure 224 can comprise substrate inward terminals 224a located on first side 221 of substrate 220 and substrate outward terminals 224b located on second side 222 of substrate 220.

Interposer substrate 320 can comprise first side 321 and second side 322 opposite to first side 321. In some examples, interposer substrate 320 can comprise dielectric structure 323 and conductive structure 324. Conductive structure 324 can comprise interposer substrate inward terminals 324a located on first side 321 of interposer substrate 320 and interposer substrate outward terminals 324b located on second side 322 of interposer substrate 320.

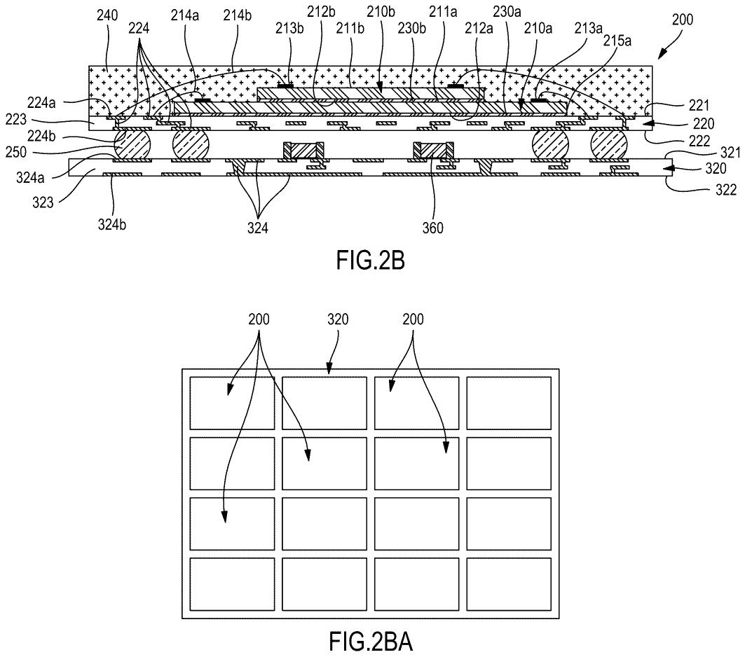

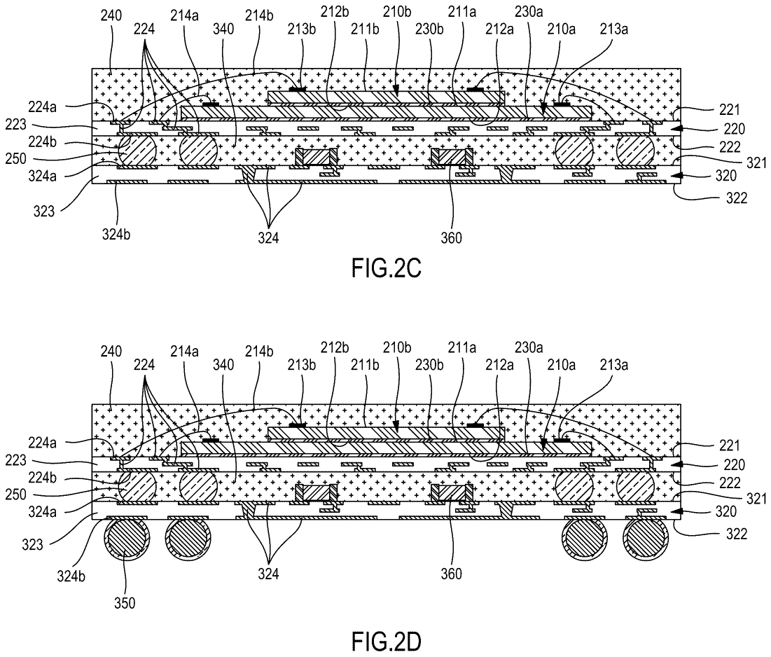

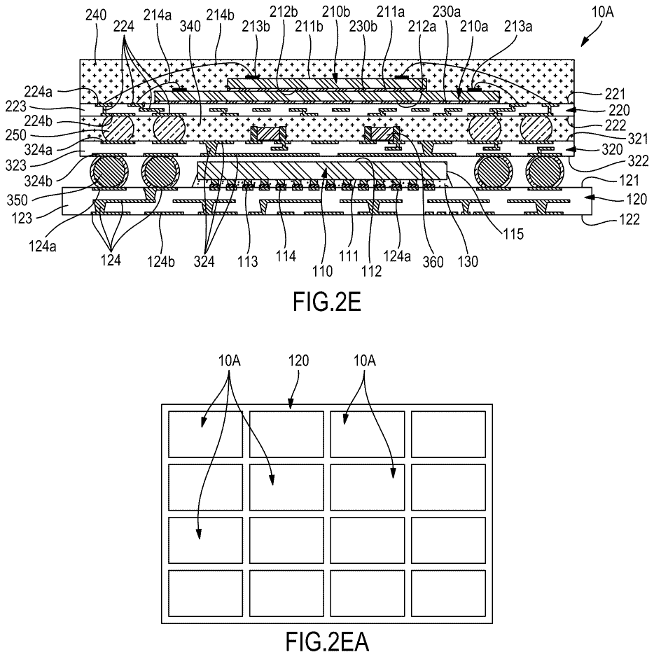

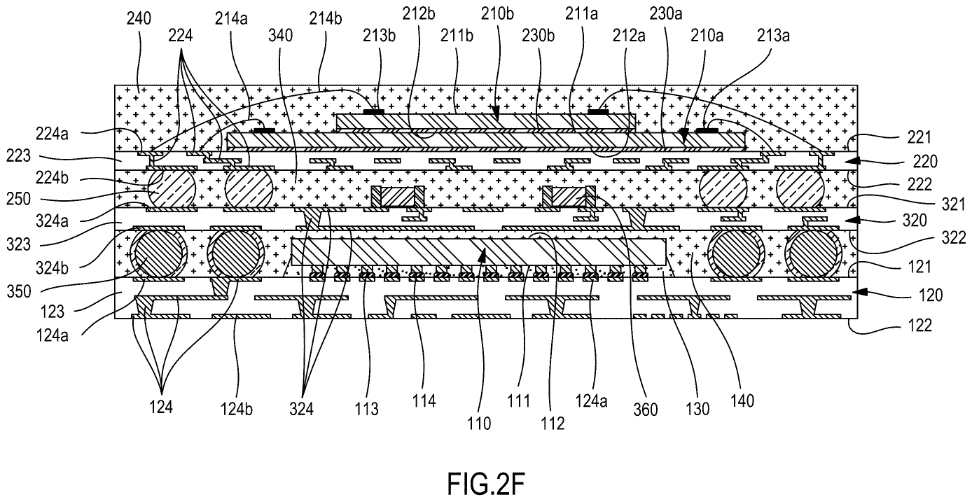

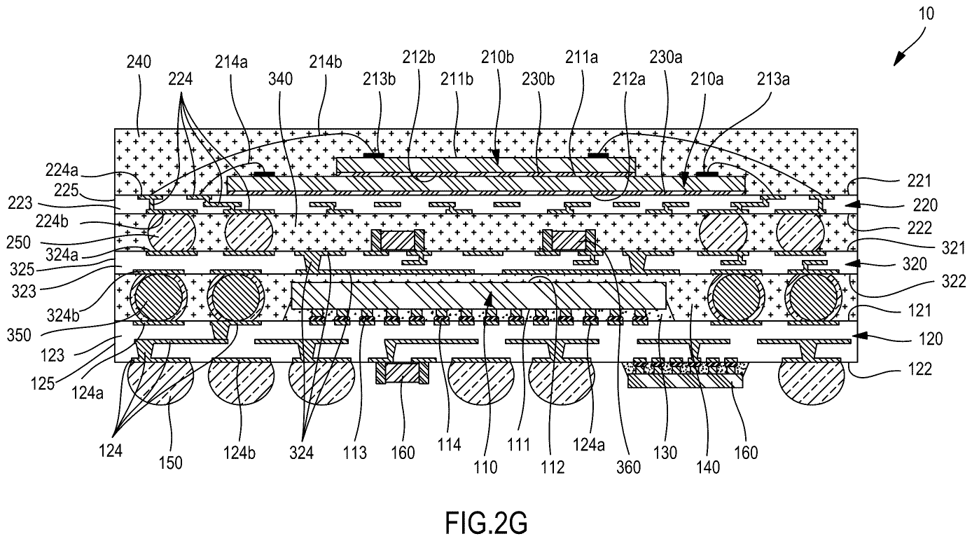

FIGS. 2A, 2B, 2C, 2D, 2E, 2F, and 2G show cross-sectional views of an example method for manufacturing an electronic device, such as packaged electronic device structure 10.

FIG. 2A shows a cross-sectional view of packaged electronic device structure 10 at an early stage of manufacture. In the example shown in FIG. 2A, interposer substrate 320 can be provided. In some examples, interposer substrate 320 can comprise a substantially planar plate structure. Interposer substrate 320 can comprise a core or can be coreless. In some examples, interposer substrate 320 can comprise or be referred to as a rigid printed circuit board, a flexible printed circuit board, a rigid laminate substrate, a flexible laminated substrate, an RDL (Redistribution Layer) substrate, a coreless substrate, a ceramic substrate, a glass substrate or a silicon substrate. In some examples, the thickness of interposer substrate 320 can vary, with a maximum range of approximately 3.5 mm (millimeter) and a core thickness falling within the range of approximately 0.05 mm to approximately 1.4 mm. In some examples, the thickness of interposer substrate 320 can range from approximately 90 microns to approximately 3500 microns. Interposer substrate 320 is configured to couple electronic components to each other and can protect the electronic components from external stress. In some examples, interposer substrate 320 can be a strip-type substrate.

Interposer substrate 320 can comprise first side 321 and second side 322 of opposite to first side 321. In some examples, first side 321 can comprise or be referred to as a first surface. In some examples, first side 321 can be configured for attaching or mounting electronic component 360 and external interconnects 250. In some examples, second side 322 of interposer substrate can comprise or be referred to as second surface. In some examples, second side 322 of interposer substrate can be configured for attaching or mounting vertical interconnects 350. In some examples, second side 322 of interposer substrate 320 can be configured for mounting to external components or boards.

Interposer substrate 320 can comprise dielectric structure 323 and conductive structure 324. In some examples, dielectric structure 323 can comprise or be referred to as one or more stacked dielectric layers. For example, the one or more dielectric layers can comprise, one or more core layers, polymer layers, pre-preg layers, or solder mask layers stacked onto each other. In some examples, one or more layers or elements of conductive structure 324 can be interleaved with dielectric structure 323. In some examples, dielectric structure 323 can comprise FR4 (copper foil/glass fiber fabric/copper foil laminate), bismaleimide triazine (BT), polyimide (PI), benzocyclobutene (BCB), polybenzoxazole (PBO), Ajinomoto Build-up Film (ABF), resin, mold compound, ceramic, glass or silicon. The thickness of individual layers of dielectric structure 323 can range from approximately 1 micron to approximately 1400 microns. Combined thickness of all layers of dielectric structure 323 can define the thickness of interposer substrate 320. Dielectric structure 323 can maintain the outer shape of interposer substrate 320 and can also structurally support conductive structure 324.

Conductive structure 324 can comprise or be referred to as one or more conductive layers defining signal distribution elements, traces, vias, pads, patterns, conductive paths, or under bump metals (UBMs). In some examples, conductive structure 324 can comprise copper, aluminum, gold, silver, nickel, palladium or an alloy. The thickness of conductive structure 324 can range from approximately 1 micron to approximately 50 microns. The thickness of conductive structure 324 can refer to individual layers of conductive structure 324. Conductive structure 324 can provide an electrical signal path (e.g., a vertical path or a horizontal path) between electronic components.

In some examples, conductive structure 324 can comprise interposer substrate inward terminals 324a provided on first side 321 of interposer substrate 320, interposer substrate outward terminals 324b provided on second side 322 of interposer substrate 320. In some examples, interposer substrate inward terminals 324a and interposer substrate outward terminals 324b can be respectively provided on first side 321 and second side 322 of interposer substrate 320 in a matrix form having rows and/or columns, respectively. In some examples, interposer substrate inward terminals 324a can comprise or be referred to as pads, lands, under-bump-metallurgy (UBM) or studs. In some examples, interposer substrate outward terminals 324b can comprise or be referred to as two-step pads, pads, or lands. In some examples, the thicknesses of interposer substrate inward terminals 324a and interposer substrate outward terminals 324b can range from approximately 5 microns to 100 microns. In some examples, conductive structure 324 can be provided in dielectric structure 323 to couple interposer substrate inward terminals 324a with interposer substrate outward terminals 324b.

In some examples, interposer substrate 320 can be a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Sᵢ₃N₄), silicon oxide (SiO₂), and/or silicon oxynitride SiON. The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Other substrates in this description can also comprise an RDL substrate.

In some examples, interposer substrate 320 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Other substrates in this description can also comprise a pre-formed substrate. Substrate 220 is an example of a first substrate.

FIG. 2B shows a cross-sectional view of packaged electronic device structure 10 at a later stage of manufacture. FIG. 2BA shows a plan view of packaged electronic device structure 10 at the later stage shown in FIG. 2B.

In the example shown in FIGS. 2B and 2BA, electronic device(s) 200 can be provided on first side 321 of interposer substrate 320. In some examples, electronic devices 200 are provided on first side 321 in a matrix arrangement. In some examples, electronic device 200 can comprise electronic component 210a, electronic component 210b, substrate 220, die attach material 230a, die attach material 230b, encapsulant 240, and external interconnects 250.

Substrate 220 can comprise first side 221 and second side 222 opposite to first side 221. In some examples, substrate 220 can comprise dielectric structure 223 and conductive structure 224. In some examples, conductive structure 224 can comprise substrate inward terminals 224a located on first side 221 and substrate outward terminals 224b located on second side 222. In some examples, substrate inward terminals 224a can be configured for mounting electronic component 210a and electronic component 210b. In some examples, substrate outward terminals 224b can be configured for mounting external interconnects 250. Substrate outward terminals 224b can be configured to be mounted on an external component or board. Substrate 220 can include corresponding elements, features, materials, or manufacturing methods similar to interposer substrate 320. First side 221 is an example of a first substrate first side, and second side 222 is an example of a first substrate second side opposite to the first substrate first side. Conductive structure 224 is an example of a first substrate conductive structure, and dielectric structure 223 is an example of a first substrate dielectric structure.

In an example, electronic component 210a can be coupled to first side 221 of substrate 220 and electronic component 210b can be coupled to electronic component 210a. In some examples, electronic component 210b is attached or mounted to electronic component 210a.

Electronic component 210a can comprise first side 211a and second side 212a opposite to first side 211a. In some examples, first side 211a can comprise or be referred to as an active side where doped regions and other device structures are provided, and second side 212a of the electronic component can comprise or be referred to as a lower side. In some examples, second 212a can comprise or be referred to as a non-active side. Electronic component 210a can comprise a lateral side 215a connecting first side 211a to second side 212a. In some examples, electronic component 210a can comprise or be referred to as a die, a chip, or a package.

In some examples, second side 212a of electronic component 210a can be coupled, attached, or fixed to first side 221 of substrate 220 through, with, or using die attach material 230a. For example, after die attach material 230a is applied or attached to first side 221 of substrate 220, pick-and-place equipment can pick up electronic component 210a and place electronic component 210a on top of die attach material 230a, and thus electronic component 210a and substrate 220 can be bonded together. In some examples, die attach material 230a can be provided on first side 221 of substrate 220 by a coating method such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of a bonding film or bonding tape. In some examples, die attach material 230a can comprise or be referred to as an adhesive, adhesive layer, or adhesive film.

In some examples, electronic component 210a can comprise contact pads 213a on first side 211a. Contact pads 213a can be input/output terminals for electronic component 210a. In some examples, contact pads 213a can be provided on first side 211a to be spaced apart from each other in a row or column direction. In some examples, contact pads 213a can be bond pads exposed through a dielectric, such as silicon oxide film (SiO₂) or a silicon nitride film (SiN), or redistribution layer pads exposed by a dielectric. In some examples, contact pads 213a can comprise an electrically conductive material such as a metallic material, aluminum, copper, an aluminum alloy, a copper alloy, combinations thereof, or other materials as known to one of ordinary skill in the art.

In some examples, electronic device 200 can comprise interconnects 214a that are configured to couple contact pads 213a of electronic component 210a to substrate 220. In some examples, interconnects 214a can comprise or be referred to as wires, leads, tabs, or clips. In some examples, interconnects 214a can comprise copper coated with gold, copper, aluminum, or palladium. In some examples, interconnects 214a can be in the form of wires and bonded to contact pads 213a of electronic component 210a by using wire bonding equipment and then bonded to substrate inward terminals 224a of substrate 220. Interconnects 214a can electrically connect contact pads 213a of electronic component 210a and substrate inward terminals 224a of substrate 220. In some examples, the thicknesses of interconnects 214a can range from approximately 10 microns to approximately 100 microns.

In some examples, electronic component 210a can be mounted to first side 221 of substrate 220 in a flip-chip configuration with contact pads 213a facing first side 221. In some examples, in electronic component 210a, contact pads 213a can be connected to substrate inward terminals 224a of substrate 220 by interconnects, such as bumps, tin lead (SnPb) bumps, leadfree bumps, CuP, stud bumps, pillars, or posts.

In some examples, the total thickness of electronic component 210a can range from approximately 50 microns to approximately 500 microns. In some examples, the area of electronic component 210a can be smaller than the area of substrate 220 and larger than the area of electronic component 210b. Electronic component 210a can be an example of a first electronic component.

Electronic component 210b can comprise first side 211b and second side 212b opposite to first side 211b. In some examples, second side 212b of electronic component 210b can be coupled to first side 211a of electronic component 210a. In some examples, second 212b can be bonded and fixed to first side 211a by die attach material 230b. Die attach material 230b can include corresponding elements, features, materials, or manufacturing methods similar to those of die attach material 230a.

Electronic component 210b can comprise contact pads 213b provided on first side 211b. Electronic device 200 can comprise interconnects 214b that electrically connects contact pads 213b to substrate inward terminals 224a of substrate 220 or to contact pads 213a of electronic component 210a. Electronic component 210b can include corresponding elements, features, materials, or manufacturing methods similar to those of electronic component 210a. Electronic component 210b can be an example of a second electronic component or a third electronic component.

In some examples, encapsulant 240 can cover first side 221 of the substrate 220, electronic component 210a, electronic component 210b, die attach material 230a and die attach material 230b. Encapsulant 240 can comprise or be referred to as a body or a molding. For example, encapsulant 240 can comprise or be referred to as an epoxy molding compound, a resin, a filler-reinforced polymer, a B-stage compressed film, or gel. Encapsulant 240 can be provided by compression molding, transfer molding, liquid body molding, vacuum lamination, paste printing, or film assisted molding. In some examples, encapsulant 240 can be in contact with first side 221 of substrate 220, first side 211a of electronic component 210a, first side 211b of electronic component 210b, the sidewalls of die attach material 230a and die attach material 230b, interconnects 214a, and interconnects 214b. In some examples, the thickness of encapsulant 240 can range from approximately 150 microns to approximately 1000 microns. Encapsulant 240 can protect electronic component 210a and electronic component 210b from external environments. In some examples, the sidewall of encapsulant 240 can be coplanar with the sidewall of substrate 220. Encapsulant 240 is an example of a first encapsulant.

In some examples, external interconnects 250 can be coupled to substrate outward terminals 224b. In some examples, external interconnects 250 can comprise tin (Sn), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, external interconnects 250 can be formed by forming a conductive material containing solder on the substrate outward terminals (224b) using a ball drop method and then performing a reflow process. External interconnects 250 can comprise or be referred to as conductive balls, such as solder balls, conductive pillars, such as copper pillars, conductive posts having solder caps provided on copper pillars, bumps, or pads. In some examples, the sizes of external interconnects 250 can range from approximately 50 microns to approximately 1000 microns. In some examples, external interconnects 250 can be referred to as external input/output terminals of electronic device 200. In some examples, electronic device 200 can be a land grid array (LGA) where, substrate outward terminals 224b serve as external input/output terminals without external interconnects 250. External interconnects 250 are an example of first external interconnects.

In electronic device 200, external interconnects 250 can be coupled to interposer substrate inward terminals 324a. In some examples, electronic device 200 can be picked up using pick-and-place equipment and placed on first side 321 of interposer substrate 320 so that external interconnects 250 can be in contact with interposer substrate inward terminals 324a. Subsequently, external interconnects 250 of electronic device 200 can be in contact with and be bonded to interposer substrate inward terminals 324a through a reflow or thermocompression bonding process. Electronic component 210a and electronic component 210b can be coupled including electrically coupled to conductive structure 324 of interposer substrate 320 through interconnects 214a, interconnects 214b, conductive structure 224 of substrate 220, and external interconnects 250. Electronic device 200 can be placed on interposer substrate 320 after electronic device 200 has been tested and determined to pass electrical and physical test parameters. That is, electronic device 200 can be placed as a known good unit or device, which, among other things, improves finished goods yields and manufacturing costs.

In some examples, electronic devices 200 can be mounted on strip-type interposer substrate 320 in a matrix form having rows or columns. In some examples, the area of electronic device 200 can be smaller than the area of interposer substrate 320. In some examples, the total thickness of electronic device 200 can range from approximately 500 microns to approximately 1500 microns, and the area of electronic device 200 can range from approximately 10 mm×10 mm to approximately 30 mm×30 mm. Electronic device 200 is an example of a first electronic device. In some examples, electronic device 200 comprises a memory device.

Before electronic device 200 is provided to first side 321 of interposer substrate 320, one or more electronic components 360 can be provided on first side 321 of interposer substrate 320. In some examples, electronic components 360 can be located between electronic device 200 and interposer substrate 320. Electronic components 360 can be in contact with and be electrically connected to interposer substrate inward terminals 324a. Electronic components 360 can be laterally spaced apart from external interconnects 250 of electronic device 200. In some examples, electronic component 360 can comprise or be referred to as a passive or active component. The thickness of electronic component 360 can be smaller than the height of external interconnects 250. In some examples, one or more electronic components 360 can be coupled including mounted to second side 222 of substrate 220. Interposer substrate 320 is an example of a second substrate. Electronic component 360 is an example of a second electronic component, a third electronic component, or a fourth electronic component.

FIG. 2C shows a cross-sectional view of packaged electronic device structure 10 at a later stage of manufacture. In the example shown in FIG. 2C, encapsulant 340 can be provided between substrate 220 and interposer substrate 320. Encapsulant 340 can fill a space between second side 222 of substrate 220 and first side 321 of interposer substrate 320. In accordance with the present description, encapsulant 340 is provided before interposer substrate 320 is coupled to primary substrate 120 (FIG. 2E). In some examples, encapsulant 340 is provided before vertical interconnects 350 are coupled to second side 322 of interposer substrate 320. More particularly the manufacturing step of providing encapsulant 340 occurs before the step of coupling vertical interconnects 350 to second side 322 of interposer substrate 320. Stated another way, second side 322 of interposer substrate 320 is devoid of vertical interconnects 350 when encapsulant 340 is provided.

Encapsulant 340 can be in contact with second side 222 of substrate 220, first side 321 of interposer substrate 320, external interconnects 250, and electronic components 360. Encapsulant 340 can comprise or be referred to as a body, a package body, or a molding. In some examples, encapsulant 340 can comprise an epoxy molding compound, a resin, a filler-reinforced polymer, a B-stage compressed film, or gel. Encapsulant 340 can be provided by compression molding or transfer molding. In the present description, encapsulant 340 is other than an underfill material including an underfill material provided using capillary dispense techniques. In this way, encapsulant 340 eliminates the need to consider KOZ requirements of underfill materials, which avoids having to increase the spacing between external interconnects 250 and the size of substrate 220 or interposer substrate 320. In addition, in some examples encapsulant 340 is provided without using film assist molding or other expensive molding techniques, which avoids added manufacturing complexities and costs. For example, if interposer substrate 320 were to be attached first to primary substrate 120 before electronic device 200 is attached to first side 321 of interposer substrate 320, expensive, specialized, and time intensive molding techniques would be required to protect first side 321 of interposer substrate 320 to avoid issues, such as mold flash contamination. In the present description, transfer molding techniques can be used because, among other things, electronic device 200 shields or protects first side 321 of interposer substrate 320 during the transfer molding process.

In some examples, the thickness of encapsulant 340 can range from approximately 100 microns to 1000 microns. Encapsulant 340 can protect external interconnects 250 and electronic components 360, thereby improving reliability. In some examples, encapsulant 240 and encapsulant 340 can comprise the same material. In some examples, encapsulant 240 and encapsulant 340 can comprise different materials with different coefficients of thermal expansion. In some examples, the materials and process techniques are chosen to reduce stress and warping of packaged electronic device structure 10 Encapsulant 340 is an example of a second encapsulant.

After encapsulant 340 is provided, encapsulant 340 and interposer substrate 320 can be singulated using, for example, a saw or laser process, to separate electronic devices 10 into individual electronic devices. Sawing can be performed so the sidewall of encapsulant 340 and the sidewall of interposer substrate 320 can be coplanar with the sidewall of electronic device 200. In the present example, the subassembly as shown in FIG. 2C with encapsulant 340 can be electrically tested before attachment to primary substrate 120 so that the subassembly can be confirmed as a known good unit before additional processing. Among other things, this improves yields and reduces manufacturing costs.

FIG. 2D shows a cross-sectional view of packaged electronic device structure 10 at a later stage of manufacture. In the example shown in FIG. 2D, vertical interconnects 350 can be provided coupled to second side 322 of interposer substrate 320.

In some examples, vertical interconnects 350 can be in contact with and be electrically connected to interposer substrate outward terminals 324b of interposer substrate 320. In some examples, vertical interconnects 350 can be arranged along one or more rows or columns along the edge of second side 322 of interposer substrate. For example, the central area of second side 322 can be devoid of or absent any vertical interconnects 350.

Vertical interconnects 350 can be electrically connected to electronic component 210a and electronic component 210b through interposer substrate 320, external interconnects 250, substrate 220, interconnects 214a, and interconnects 214b.

In some examples, vertical interconnects 350 can comprise or be referred to as solder balls, bumps, pillars, posts, copper cube columns (CCCs), metallic core balls, stacked balls, through mold vias (TMVs), or wires. In some examples, vertical interconnects 350 can comprise tin (Sn), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. In some examples, vertical interconnects 350 can be formed by a ball drop method, a screen-printing method, or an electrolytic plating method. In some examples, vertical interconnects 350 can be provided by providing solder-coated metal core balls to interposer substrate outward terminals 324b of interposer substrate 320 through a ball drop method, and then through a reflow process. The heights of vertical interconnects 350 can range from approximately 100 microns to approximately 500 microns.

FIG. 2E shows a cross-sectional view of packaged electronic device structure 10 at a later stage of manufacture. FIG. 2EA shows a plan view of packaged electronic device structure 10 shown in FIG. 2E in a later stage of manufacture. In the example shown in FIGS. 2E and 2EA, packaged electronic device subassembly 10A including vertical interconnects 350 can be provided on first side 121 of primary substrate 120. Here, packaged electronic device subassembly 10A can be an electronic device manufactured through the manufacturing process of FIGS. 2A to 2D. In some examples, packaged electronic device subassembly 10A can comprise electronic component 210a, electronic component 210b, electronic component 360, substrate 220, die attach material 230a, die attach material 230b, encapsulant 240, encapsulant 340, external interconnects 250, interposer substrate 320, and vertical interconnects 350.

Primary substrate 120 can comprise first side 121 and second side 122 opposite to first side 121. In some examples, primary substrate 120 can comprise dielectric structure 123 and conductive structure 124. Conductive structure 124 can comprise primary substrate inward terminals 124a located on first side 121, and primary substrate outward terminals 124b located on second side 122. Primary substrate inward terminals 124a can be configured for mounting or attaching electronic component 110, and for mounting or attaching packaged electronic device subassembly 10A. In some examples, primary substrate can be configured for mounting or attaching primary external interconnects 150. In some examples, primary external interconnects 150 can be configured for coupling to an external component or a board. Primary substrate 120 can include corresponding elements, features, materials, or manufacturing methods similar to those of interposer substrate 320. The total thickness of primary substrate 120 can range from approximately 100 microns to approximately 500 microns, and the area of electronic device 200 can range from approximately 50 mm×500 mm to approximately 100 mm×1000 mm. Primary substrate 120 can be of a strip type. Primary substrate 120 is an example of a third substrate.

In packaged electronic device subassembly 10A, vertical interconnects 350 can be in contact with and be electrically connected to primary substrate inward terminals 124a. For example, packaged electronic device subassembly 10A can be picked up through pick-and-place equipment and placed on first side 121 of primary substrate 120 so that vertical interconnects 350 are in contact with primary substrate inward terminals 124a. Subsequently, vertical interconnects 350 can be in contact with and be bonded to primary substrate inward terminals 124a through a reflow or thermocompression bonding process. Electronic component 210a and electronic component 210b can be electrically connected to primary substrate 120 through interconnects 214a, interconnects 214b, substrate 220, external interconnects 250, interposer substrate 320, and vertical interconnects 350. Packaged electronic device subassembly 10A can be placed on primary substrate 120 after packaged electronic device subassembly 10A has been tested and determined to pass electrical and physical test parameters. That is, packaged electronic device subassembly 10A can be placed as a known good unit or device, which, among other things, improves finished goods yields and manufacturing costs. Electronic devices 10A can be mounted on strip-type primary substrate 120 in a matrix form having rows or columns. The area of packaged electronic device subassembly 10A can be smaller than the area of primary substrate 120. The area of packaged electronic device subassembly 10A can be similar to the area of electronic device 200.

Before packaged electronic device subassembly 10A is provided to primary substrate 120, electronic component 110 can be coupled to first side 121 of primary substrate 120. In some examples, electronic component 110 can be in contact with and be electrically connected to primary substrate inward terminals 124a of primary substrate 120. In some examples, electronic component 110 can be provided in a central area on first side 121 of primary substrate 120. Electronic component 110 and vertical interconnects 350 are laterally separated from each other. Electronic component 110 can comprise first side 111 and second side 112 opposite to first side 111. In some examples, first side 111 can comprise or be referred to as an active side, and second side 112 can comprise or be referred to as a lower side. In some examples, second side 112 can comprise or be referred to as inactive side. Electronic component 110 can comprise a lateral side 115 connecting first side 111 and second side 112.

Electronic component 110 can comprise contact pads 113 on first side 111, which can be provided spaced apart from each other in a row or column direction. In some examples, contact pads 113 can comprise bond pads exposed through a dielectric, such as a silicon oxide film (SiO₂) or a silicon nitride film (SiN), or redistribution layer pads exposed by a dielectric. In some examples, contact pads 113 can comprise an electrically conductive material such as a metallic material, aluminum, copper, an aluminum alloy, or a copper alloy.

In some examples, interconnects 114 can couple contact pads 113 to primary substrate 120. In some examples, interconnects 114 electrically connect contact pads 113 to substrate inward terminals 124a. In some examples, interconnects 114 can comprise or be referred to as bumps, SnPb bumps, leadfree bumps, CuP, stud bumps, pillars, or posts. In some examples, interconnects 114 can be provided on contact pads 113 of the electronic component by plating or a ball drop method. In some examples, interconnects 114 are provided as part of electronic component 110 as part of a wafer fabrication process.

In some examples, pick-and-place equipment can pick up electronic component 110 and place electronic component 110 on first side 121 of primary substrate 120. In some examples, interconnects 114 of electronic component 110 can be located on top of primary substrate inward terminals 124a of primary substrate 120. Subsequently, contact pads 113 can be in contact with and be bonded to primary substrate inward terminals 124a through interconnects 114 by a reflow or thermal compression bonding process. In some examples, electronic component 110 can comprise or be referred to as a die, a chip, or a package. Electronic component 110 is an example of a second electronic component, a third electronic component, or a fourth electronic component. Primary substrate 120 and electronic component 110 are an example of a second electronic device.

In some examples, underfill material 130 can be positioned between electronic component 110 and primary substrate 120. Underfill material 130 can be in contact with first side 111 of electronic component 110 and first side 121 of primary substrate 120. Underfill material 130 can be in contact with contact pads 113 and interconnects 114. Underfill material 130 can comprise or be referred to as a dielectric layer or a non-conductive paste and can be free of inorganic fillers. In some examples, underfill material 130 can comprise capillary underfill (CUF), nonconductive paste (NCP), nonconductive film (NCF), anisotropic conductive film (ACF), or anisotropic conductive paste (ACP). In some examples, when underfill material 130 comprises a molded underfill (MUF), electronic component 110 including contact pads and interconnects 114 can be covered by encapsulant 140, and underfill material 130 can be considered a part of or replaced by encapsulant 140. In some examples, underfill material 130 can be provided between electronic component 110 and primary substrate 120 and then cured. In some examples, after underfill material 130 is provided to cover the inside of primary substrate 120, interconnects 114 of electronic component 110 can penetrate underfill material 130 to be connected to primary substrate inward terminals 124a. Underfill material 130 can prevent electronic component 110 from being separated from primary substrate 120 due to physical and chemical impact.

Although electronic component 110 is shown as being in a face-down or flip-chip configuration, electronic component 110 can be in a face-up or wire-bonding configuration. For example, in electronic component 110, the inactive side, second side 112 of the electronic component, can be bonded to first side 121 of primary substrate 120, and primary substrate inward terminals 124a and contact pads 113 can be electrically connected to each other through conductive wires or other types of interconnects. In some examples, the total thickness of electronic component 110 can range from approximately 50 microns to approximately 200 microns, and the area of electronic device 200 can range from approximately 0.5 mm×0.5 mm to approximately 50 mm×50 mm. The total thickness of electronic component 110 can be smaller than the thicknesses of vertical interconnects 350. Second side 112 of electronic component 110 can be spaced apart from second side 322 of interposer substrate 320.

FIG. 2F shows a cross-sectional view of packaged electronic device structure 10 at a later stage of manufacture. In the example shown in FIG. 2F, encapsulant 140 can be provided between primary substrate 120 and interposer substrate 320. Encapsulant 140 can fill a space between first side 121 of primary substrate 120 and second side 322 of interposer substrate 320. Encapsulant 140 can be in contact with first side 121 of primary substrate 120, second side 322 of interposer substrate 320, electronic component 110 (including second side 112), and vertical interconnects 350. Encapsulant 140 can include corresponding elements, features, materials, or manufacturing methods similar to those of encapsulant 340. In some examples, encapsulant 240, encapsulant 340, and encapsulant 140 can comprise different materials with different coefficients of thermal expansion. In some examples, the materials and processing techniques are chosen to reduce stress and warping of packaged electronic device structure 10. Encapsulant 140 is an example of a third encapsulant.

Encapsulant 140 can protect electronic component 110 and vertical interconnects 350, thereby improving reliability. After encapsulant 140 is provided, encapsulant 140 and primary substrate 120 can be singulated using, for example, a sawing or laser process, to separate packaged electronic device subassembly 10A into individual electronic devices. In some examples, the singulation can be performed so the sidewall of encapsulant 140 and the sidewall of primary substrate 120 can be coplanar with the sidewall of packaged electronic device subassembly 10A. In addition, with the presence of external interconnects 250 and encapsulant 340, first side 321 including inward terminals 324a are protected against defects such as mold flash when encapsulant 140 is provided.

FIG. 2G shows a cross-sectional view of packaged electronic device structure 10 at a later stage of manufacture. In the example shown in FIG. 2G, primary external interconnects 150 can be provided on second side 122 of primary substrate 120. In some examples, primary external interconnects 150 are coupled to primary substrate outward terminals 124b. Primary external interconnects 150 can be in contact with and be electrically connected to primary substrate outward terminals 124b. Primary external interconnects 150 can include corresponding elements, features, materials, or manufacturing methods similar to those of external interconnects 250. Primary external interconnects 150 are an example of second external interconnects.

In some examples, before primary external interconnects 150 are provided, one or more electronic components 160 can be coupled to second side 122 of primary substrate 120. Electronic components 160 can be in contact with and can be electrically connected to primary substrate outward terminals 124b. Electronic components 160 can be laterally spaced apart from primary external interconnects 150 on a plane. In some examples, electronic components 160 can comprise or be referred to as a passive or active component. Electronic component 160 is an example of a third electronic component, a fourth electronic component, or a fifth electronic component.

Primary external interconnects 150 can be electrically connected to electronic components 160 or electronic component 110 through primary substrate 120. Primary external interconnects 150 can be electrically connected to electronic component 360 through primary substrate 120, vertical interconnects 350, and interposer substrate 320. Primary external interconnects 150 can be electrically connected to electronic component 210a and electronic component 210b through primary substrate 120, vertical interconnects 350, interposer substrate 320, external interconnects 250, and substrate 220. In some examples, electronic components 110, 160, 210a, 210b, and 360 can be electrically connected to each other through primary substrate 120, vertical interconnects 350, interposer substrate 320, external interconnects 250, and substrate 220.

Packaged electronic device structure 10 can comprise electronic component 110, electronic component 210a, electronic component 210b, electronic components 160, electronic components 360, primary substrate 120, underfill material 130, encapsulant 140, encapsulant 240, encapsulant 340, primary external interconnects 150, substrate 220, die attach material 230a, die attach material 230b, external interconnects 250, interposer substrate 320, and vertical interconnects 350. In packaged electronic device structure 10, encapsulant 340 can be provided and located between primary substrate 120 and interposer substrate 320, and encapsulant 140 can be located between interposer substrate 320 and primary substrate 120. By means of encapsulant 140 and encapsulant 340, packaged electronic device structure 10 can protect vertical interconnects 350, external interconnects 250, electronic component 110, and electronic component 360, thereby improving the reliability.

In some examples, substrate 220 comprises lateral side 225 connecting first side 221 to second side 222, interposer substrate 320 comprises a lateral side 325 connecting first side 321 to second side 322, and primary substrate 120 comprises a lateral side 125 connecting first side 121 to second side 122. In some examples, lateral side 225, lateral side 325, and lateral side 125 are substantially coplanar with each other. In some examples, lateral side 225 is exposed from encapsulant 240 and encapsulant 340, lateral side 325 is exposed from encapsulant 340 and encapsulant 140, and lateral side 125 is exposed from encapsulant 140. This configuration can also apply to packaged electronic device structure 20.

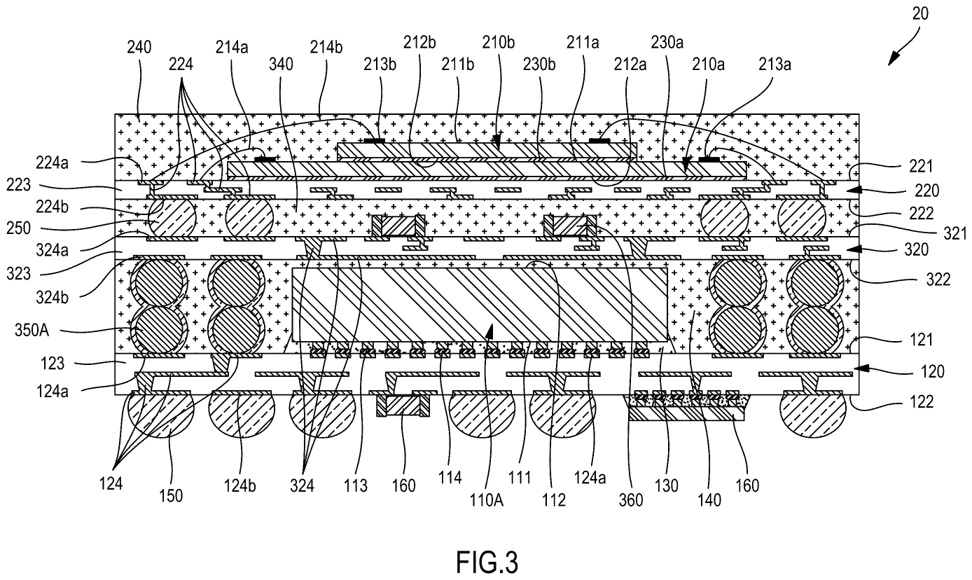

FIG. 3 shows a cross-sectional view of packaged electronic device 20. In the example shown in FIG. 3, packaged electronic device 20 can comprise electronic component 110A, electronic component 210a, electronic component 210b, electronic components 160, electronic components 360, primary substrate 120, underfill material 130, encapsulant 140, encapsulant 240, encapsulant 340, primary external interconnects 150, substrate 220, die attach material 230a, die attach material 230b, external interconnects 250, interposer substrate 320, and vertical interconnects 350A.

In the present example, packaged electronic device 20 has similarity to packaged electronic device structure 10; however, in packaged electronic device 20, the overall thickness of electronic component 110A and the heights of vertical interconnects 350A can range from approximately 200 microns to approximately 1000 microns. In the present examples, the thickness of electronic component 110A can be increased, thereby increasing thermal performance efficiency of packaged electronic device 20. In some examples, the thickness of electronic component 110A is greater than the combined thicknesses of electronic component 210a and electronic component 210b. In some examples, vertical interconnects 350A can be made of dual core balls provided in a stacked configuration to prevent pitches from increasing due to an increase in the height. This maintains a smaller package footprint. Electronic component 110A is an example of a fourth electronic component.

In some examples, vertical interconnects 350A can be provided in the stacked configuration by bonding the core balls to each other through a reflow process in a state where a first core ball is provided on second side 322 of interposer substrate 320 and a second core ball is provided on first side 121 of primary substrate 120. Vertical interconnects 350A can be made of dual core balls to prevent pitches from increasing due to an increase in the height of electronic component 110A, thereby realizing a fine pitch. Electronic component 110A can include corresponding elements, features, materials, or manufacturing methods similar to those of electronic component 110 of packaged electronic device structure 10, except electronic component 110A has a greater thickness.

In summary, structures and methods have been described that relate to packaged electronic components having improved manufacturability, quality, and reliability. More particularly, structures and methods have been described that provide a molded encapsulant within a gap between the top side of an interposer substrate and an electronic component mounted the top side to protect interconnects coupling the electronic component to the interposer substrate. In some examples, a transfer molding process is used to provide the molded encapsulant between the electronic component and the top side of the interposer substrate prior to attaching the interposer substrate to a primary or bottom substrate. The molded encapsulant has advantages over other materials, such as capillary underfill materials, including no need for keep out zone considerations, which unfavorably increase package size. Also, the approach avoids using tape assisted processing or other expensive molding techniques, which reduces process complexities and costs. Further, the approach allows for electrical testing before the interposer substrate is attached to the primary substrate, which improves yields and saves on manufacturing costs.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. A packaged electronic device structure, comprising:
a first electronic device comprising:
a first substrate comprising:
a first substrate first side and a first substrate second side opposite the first substrate first side; and
a first substrate conductive structure;
a first electronic component coupled to the first substrate conductive structure at the first substrate first side;
a first encapsulant covering the first electronic component; and
first external interconnects coupled to the first substrate conductive structure at the first substrate second side;
a second substrate comprising:
a second substrate first side and a second substrate second side opposite the second substrate first side;
a second substrate conductive structure; and
a second substrate dielectric structure, wherein:
the first external interconnects are coupled to the second substrate conductive structure at the second substrate first side;
a second electronic component coupled to the second substrate first side;
a second encapsulant interposed between the first substrate and the second substrate and covering the first external interconnects, the second substrate first side, the first substrate second side, and the second electronic component;
a second electronic device comprising:
a third substrate comprising:
a third substrate first side and a third substrate second side opposite to the third substrate first side; and
a third substrate conductive structure; and
a third electronic component coupled to the third substrate conductive structure at the third substrate first side;
vertical interconnects coupled to the second substrate conductive structure at the second substrate second side and coupled to the third substrate conductive structure at the third substrate first side;
a third encapsulant interposed between the second substrate and the third substrate and covering the vertical interconnects and the third electronic component; and
second external interconnects coupled the third substrate conductive structure at the third substrate second side.

2. The packaged electronic device structure of claim 1, further comprising:
a fourth electronic component coupled to the first electronic component and coupled to the first substrate conductive structure, wherein:
the first encapsulant covers the third electronic component.

3. The packaged electronic device structure of claim 2, wherein:
the third electronic component comprises a thickness that is greater than combined thicknesses of the first electronic component and the fourth electronic component.

4. The packaged electronic device structure of claim 1, wherein:
the second encapsulant comprises a mold compound.

5. The packaged electronic device structure of claim 1, wherein:
the vertical interconnects comprise metallic core balls.

6. The packaged electronic device structure of claim 1, wherein:
the vertical interconnects each comprise dual core balls in a stacked configuration.

7. The packaged electronic device structure of claim 1, further comprising:
an underfill interposed between the third electronic component first side and the third substrate first side.

8. The packaged electronic device structure of claim 1, wherein:
the first substrate comprises a first substrate lateral side connecting the first substrate first side to the first substrate second side;
the second substrate comprises a second substrate lateral side connecting the second substrate first side to the second substrate second side;
the third substrate comprises a third substrate lateral side connecting the third substrate first side from the third substrate second side;
the first substrate lateral side, the second substrate lateral side, and the third substrate lateral side are substantially coplanar;
the first substrate lateral side is expose from the first encapsulant and the second encapsulant;
the second substrate lateral side is exposed from the second encapsulant and the third encapsulant; and
the third substrate lateral side is exposed from the third encapsulant.

9. A method of manufacturing a packaged electronic device structure, comprising:
providing a first electronic device comprising:
a first substrate comprising:
a first substrate first side and a first substrate second side opposite the first substrate first side; and
a first substrate conductive structure;
a first electronic component coupled to the first substrate conductive structure at the first substrate first side;
a first encapsulant covering the first electronic component; and
first external interconnects coupled to the first substrate conductive structure at the first substrate second side;
providing a second substrate comprising:
a second substrate first side and a second substrate second side opposite the second substrate first side;
a second substrate conductive structure; and
a second substrate dielectric structure;
coupling the first external interconnects to the second substrate conductive structure at the second substrate first side;
providing a second encapsulant interposed between the first substrate and the second substrate and covering the first external interconnects, the second substrate first side, and the first substrate second side;
providing first vertical interconnects coupled to the second substrate conductive structure at the second substrate second side;
providing a second electronic device comprising:
a third substrate comprising:
a third substrate first side and a third substrate second side opposite to the third substrate first side; and
a third substrate conductive structure; and
a second electronic component coupled to the third substrate conductive structure at the third substrate first side; and
after providing the second encapsulant:
(a) coupling the first vertical interconnects to the third substrate conductive structure at the third substrate first side; and
(b) providing a third encapsulant interposed between the second substrate and the third substrate and covering the first vertical interconnects and the second electronic component.

10. The method of claim 9, further comprising:
providing second vertical interconnects coupled to the third substrate conductive structure, wherein:
coupling the first vertical interconnects comprises attaching the first vertical interconnects to the second vertical interconnects; and
providing the third encapsulant comprises covering the second vertical interconnects.

11. The method of claim 10, wherein:
providing the first vertical interconnects comprises providing first metallic core balls; and
providing the second vertical interconnects comprises providing second metallic core balls.

12. The method of claim 9, wherein:
providing the second encapsulant comprises transfer molding the second encapsulant.

13. The method of claim 9, further comprising:
providing a third electronic component attached to the second substrate first side, wherein:
the second encapsulant covers the third electronic component.

14. The method of claim 9, wherein:
providing the first electronic device comprises:
providing a third electronic component coupled to the first electronic component and coupled to the first substrate conductive structure; and
providing the first encapsulant covering the third electronic component.

15. The method of claim 14, further comprising:
providing a fourth electronic component coupled to the second substrate first side before providing the second encapsulant; and
providing second external interconnects coupled the third substrate conductive structure at the third substrate second side, wherein:
the second electronic device comprises a thickness that is greater than combined thicknesses of the first electronic component and the third electronic component.

16. A method of manufacturing a packaged electronic device structure, comprising:
providing a first electronic device comprising:
a first substrate comprising:
a first substrate first side and a first substrate second side opposite the first substrate first side; and
a first substrate conductive structure;
a first electronic component coupled to the first substrate conductive structure at the first substrate first side;
a first encapsulant covering the first electronic component; and
first external interconnects coupled to the first substrate conductive structure at the first substrate second side;
providing a second substrate comprising:
a second substrate first side and a second substrate second side opposite the second substrate first side;
a second substrate conductive structure; and
a second substrate dielectric structure;
coupling the first external interconnects to the second substrate conductive structure at the second substrate first side;
providing a second encapsulant interposed between the first substrate and the second substrate and covering the first external interconnects, the second substrate first side, and the first substrate second side;
coupling first vertical interconnects to the second substrate conductive structure at the second substrate second side; and
after providing the second encapsulant:
(a) providing a second electronic device comprising:
a third substrate comprising:
a third substrate first side and a third substrate second side opposite to the third substrate first side; and
a third substrate conductive structure; and
a second electronic component coupled to the third substrate conductive structure at the third substrate first side;
(b) coupling the first vertical interconnects to the third substrate conductive structure at the third substrate first side; and
(c) providing a third encapsulant interposed between the second substrate and the third substrate and covering the first vertical interconnects and the
second electronic component.

17. The method of claim 16, further comprising:
providing second vertical interconnects coupled to the third substrate conductive structure, wherein:
coupling the first vertical interconnects comprises attaching the first vertical interconnects to the second vertical interconnects; and
providing the third encapsulant comprises covering the second vertical interconnects.

18. The method of claim 17, wherein:
providing the first vertical interconnects comprises providing first metallic core balls; and
providing the second vertical interconnects comprises providing second metallic core balls.

19. The method of claim 16, wherein:
providing the second encapsulant comprises transfer molding the second encapsulant.

20. The method of claim 16, wherein:
providing the second encapsulant occurs before coupling the first vertical interconnects to the second substrate conductive structure.
